(19) United States
(12) Patent Application Publication
(10) Pub. No.: US 2001/0002700 A1
(43) Pub. Date: Jun. 7, 2001

(54) Apparatus for optically checking a pattern and method of doing the same

(75) Inventor: Toyokazu Nakamura, Tokyo (JP)

Correspondence Address: Norman P. Soloway, HAYES, SOLOWAY, HENNESSEY,, GROSSMAN & HAGE, P.C., 175 Canal Street, Manchester, NH, 03101, US

(73) Assignee: NEC CORPORATION

(21) Appl. No.: 09/727,808

(22) Filed: Dec. 1, 2000

(30) Foreign Application Priority Data
Dec. 3, 1999 (JP) 345280/1999

(51) Int. Cl. G21K 5/10; H01J 37/08

(52) U.S. Cl. 250/492.22

(57) ABSTRACT

An apparatus for optically checking a pattern of a semiconductor wafer, includes (a) a laser beam source which radiate a laser beam to the pattern, (b) a beam collector which collects a laser beam reflected from the pattern, (c) a photodetector which detects a defect in a shape in the pattern, based on the laser beam collected by the beam collector, the laser beam source and the beam collector being movable together in an area above the semiconductor wafer.

### BACKGROUND OF THE INVENTION

1. Field of the Invention

The invention relates to an apparatus and a method for detecting a defect in a shape in a pattern, and more particularly to an apparatus and a method for optically checking a pattern of a semiconductor wafer.

2. Description of the Related Art

For instance, Japanese Unexamined Patent Publications Nos. 5-118994, 62-127652 and 8-162511 have suggested an apparatus for optically checking a pattern of a semiconductor wafer.

Such an apparatus is illustrated in FIG. 1. The illustrated apparatus is comprised of a laser beam emitter 1 emitting a laser beam 2 to a semiconductor wafer W, a beam collector 3 collecting a laser beam reflected at the semiconductor wafer W, a photodetector 4 detecting a pattern defect of the semiconductor wafer W, based on the laser beam collected by the beam collector 3, and a X-Y stage 6a movable in directions of X and Y axes.

The laser beam emitter 1 is fixed to the beam collector 3 through a connector 8. The semiconductor wafer W is fixed on the X-Y stage 6a. The laser beam emitter 1, the beam collector 3 and the photodetector 4 are stationary, whereas the X-Y stage 6a moves together with the semiconductor wafer W in directions of X and Y axes.

In operation, the X-Y stage 6a moves together with the semiconductor wafer W in order to enable the semiconductor wafer W to receive the laser beam 2 entirely at a surface of the semiconductor wafer W.

As a result, as illustrated in FIG. 2, the semiconductor wafer W has to move from a position indicated with a circle W1 to a position indicated with a circle W2 in an X-axis direction, and from a position indicated with a circle W3 to a position indicated with a circle W4 in a Y-axis direction. This means the semiconductor wafer W has to move in a circle Wx including all the circles W1 to W4 wherein Wx has a diameter about twice greater than a diameter of the semiconductor wafer W.

Thus, in order to make it possible to cover the semiconductor wafer W with the laser beam 2 emitted from the stationary laser beam emitter 1, there has to be a space for the semiconductor wafer W to move in which space is about four times greater than an area of the semiconductor wafer W.

However, such a space would cause a problem of an unavoidable increase in a size of the apparatus for optically checking a pattern of a semiconductor wafer.

### SUMMARY OF THE INVENTION

In view of the above-mentioned problems in the conventional apparatus, it is an object of the present invention to provide an apparatus which is capable of optically checking a pattern of a semiconductor wafer without a need of a large space to move in.

In one aspect of the present invention, there is provided an apparatus for optically checking a pattern of a semiconductor wafer, including (a) a laser beam source which radiate a laser beam to the pattern, (b) a beam collector which collects a laser beam reflected from the pattern, and (c) a photodetector which detects a defect in a shape in the pattern, based on the laser beam collected by the beam collector, the beam collector being movable in an area above the semiconductor wafer.

For instance, the beam collector is movable in a two-dimensional area.

It is preferable that the photodetector is integral with the beam collector such that the photodetector is movable together with the beam collector.

There is further provided an apparatus for optically checking a pattern of a semiconductor wafer, including (a) a laser beam source which radiate a laser beam to the pattern, (b) a beam collector which collects a laser beam reflected from the pattern, and (c) a photodetector which detects a defect in a shape in the pattern, based on the laser beam collected by the beam collector, the laser beam source and the beam collector being movable together in an area above the semiconductor wafer.

For instance, the laser beam source and the beam collector are movable in a two-dimensional area.

It is preferable that the photodetector is integral with the laser beam source and the beam collector such that the photodetector is movable together with the laser beam source and the beam collector.

In another aspect of the present invention, there is provided a method of optically checking a pattern of a semiconductor wafer, including the steps of (a) radiating a laser beam to the pattern, (b) moving a beam collector in an area above the semiconductor wafer for collecting a laser beam reflected from the pattern, and (c) detecting a defect in a shape in the pattern, based on the laser beam collected in the step (b).

For instance, the beam collector is moved in a two-dimensional area in the step (b).

There is further provided a method of optically checking a pattern of a semiconductor wafer, including the steps of (a) radiating a laser beam from a laser beam source to the pattern, (b) moving both the laser beam source and a beam collector in an area above the semiconductor wafer for collecting a laser beam reflected from the pattern, and (c) detecting a defect in a shape in the pattern, based on the laser beam collected in the step (b).

The advantages obtained by the aforementioned present invention will be described hereinbelow.

In accordance with the above-mentioned invention, since the laser beam source is designed to move above and relative to the semiconductor wafer. In order to make it possible to entirely cover the semiconductor wafer with a laser beam emitted from the laser beam source, it is necessary for the laser beam source to be able to move only in an area just above the semiconductor wafer. As mentioned earlier, the conventional apparatus requires a space about four times greater than an area of a semiconductor wafer in order to entirely cover the semiconductor wafer with a laser beam. Thus, the present invention needs only a space just one-fourth of a space the conventional apparatus needs for moving the laser beam emitter.

Accordingly, the apparatus in accordance with the present invention can be fabricated smaller than the conventional apparatus.

The above and other objects and advantageous features of the present invention will be made apparent from the following description made with reference to the accompanying drawings, in which like reference characters designate the same or similar parts throughout the drawings.

### BRIEF DESCRIPTION OF THE DRAWINGS

FIG. 1 is a side view of a conventional apparatus for optically checking a pattern of a semiconductor wafer.

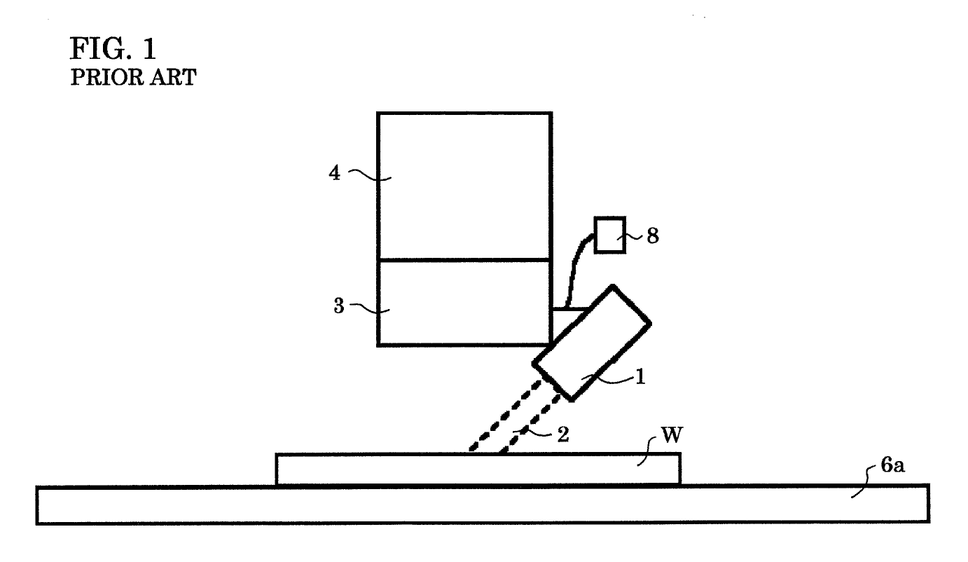

FIG. 2 is a top view of the apparatus illustrated in FIG. 1.

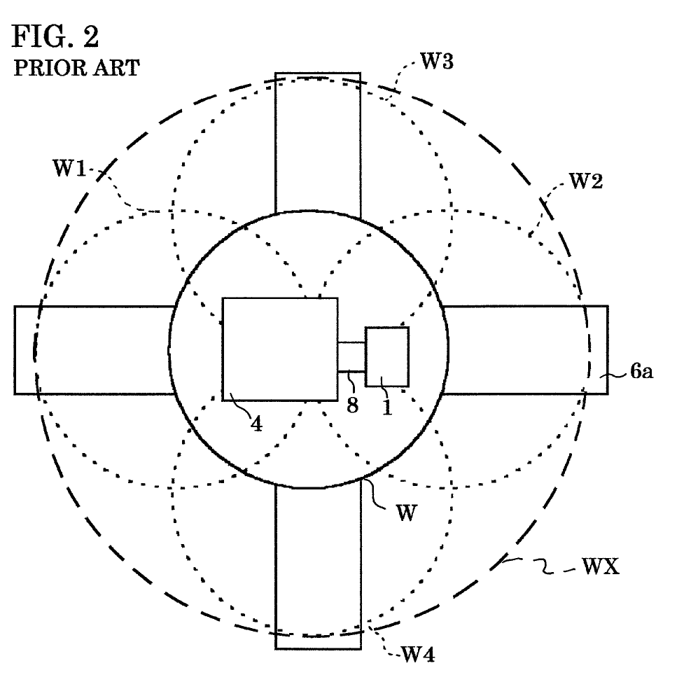

FIG. 3 is a side view of an apparatus for optically checking a pattern of a semiconductor wafer, in accordance with the first embodiment of the present invention.

FIG. 4 is a top view of the apparatus illustrated in FIG. 3.

FIG. 5 is a side view of an apparatus for optically checking a pattern of a semiconductor wafer, in accordance with the second embodiment of the present invention.

FIG. 6 is a top view of the apparatus illustrated in FIG. 5.

### DESCRIPTION OF THE PREFERRED EMBODIMENTS

### First Embodiment

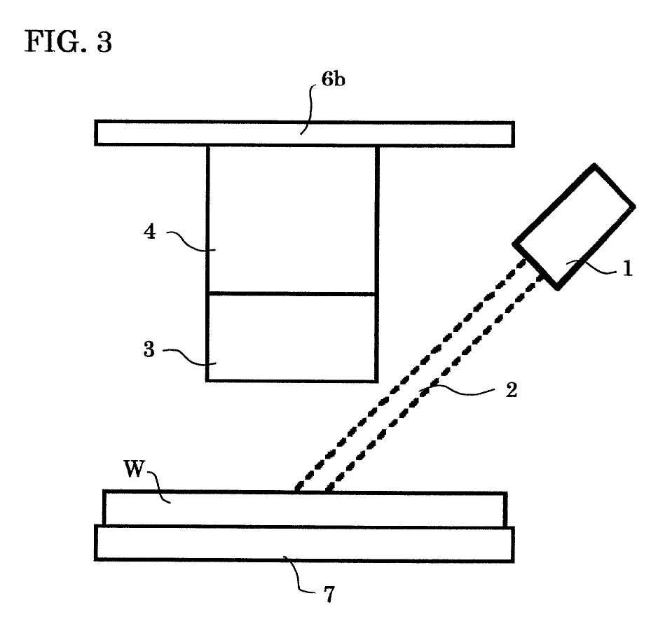

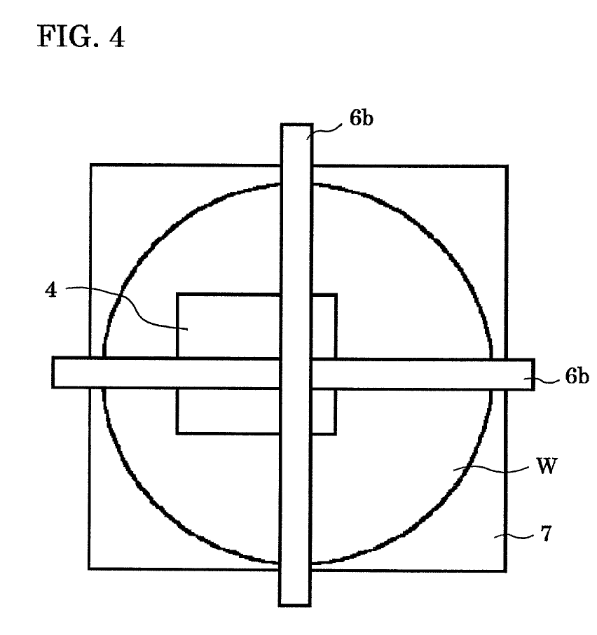

FIGS. 3 and 4 illustrate an apparatus for optically checking a pattern of a semiconductor wafer, in accordance with the first embodiment. FIG. 3 is a side view of the apparatus, and FIG. 4 is a top view of the apparatus.

The apparatus is comprised of a laser beam emitter 1 which emits a laser beam 2 to a semiconductor wafer W, a beam collector 3 which collects a laser beam reflected by the semiconductor wafer W, a photodetector 4, comprised of a CCD array in the first embodiment, which detects a pattern defect of the semiconductor wafer W, based on the laser beam collected by the beam collector 3, a X-Y stage 6b movable in directions of X and Y axes, and a stationary table 7 on which the semiconductor wafer W is placed.

The beam collector 3 and the photodetector 4 are both mounted on a lower surface of the X-Y stage 6b. Hence, the beam collector 3 and the photodetector 4 move together in directions of X and Y axes together wit the X-Y table 6b. That is, the beam collector 3 can move to anywhere in an area above the semiconductor wafer W.

In contrast, the laser beam emitter 1 is fixed to a support (not illustrated), and hence, is kept stationary relative to the beam collector 3 and the photodetector 4. The laser beam emitter 1 is designed to swing in horizontal and vertical directions such that the laser beam 2 emitted therefrom can entirely cover the semiconductor wafer W.

In operation, the laser beam emitter 1 radiates the laser beam 2 to the semiconductor wafer W fixed on the stationary table 7. The laser beam 2 would be diffracted or scattered, if the laser beam 2 is reflected at a pattern defect.

The beam collector 3 collects the reflected laser beams 2, and focuses the thus collected laser beams 2 on the photodetector 4 to thereby form images in the photodetector 4. Based on the images, a pattern defect is detected.

In the first embodiment, since the laser beam emitter 1 is designed to move above to the semiconductor wafer W. In order to make it possible to entirely cover the semiconductor wafer W with the laser beam 2, it is necessary for the laser beam emitter 1 to be able to move in an area just above the semiconductor wafer W. As mentioned earlier, the conventional apparatus requires a space about four times greater than an area of a semiconductor wafer in order to entirely cover the semiconductor wafer with a laser beam. Thus, the apparatus in accordance with the first embodiment needs a space just one-fourth of a space the conventional apparatus needs for moving the laser beam emitter.

### Second Embodiment

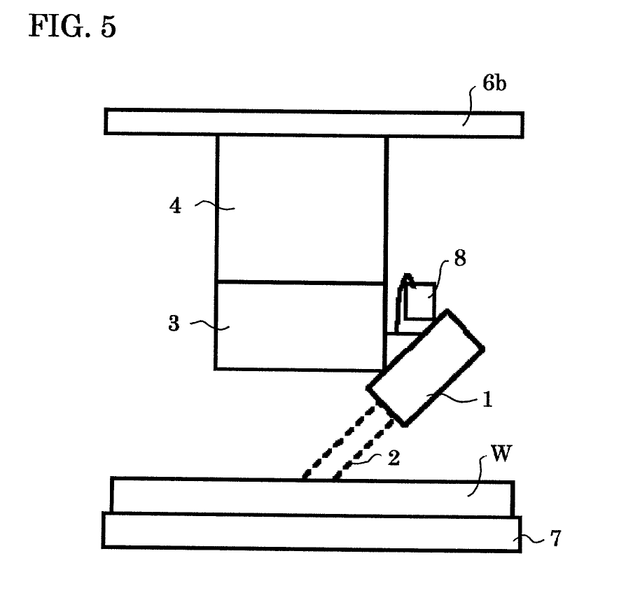

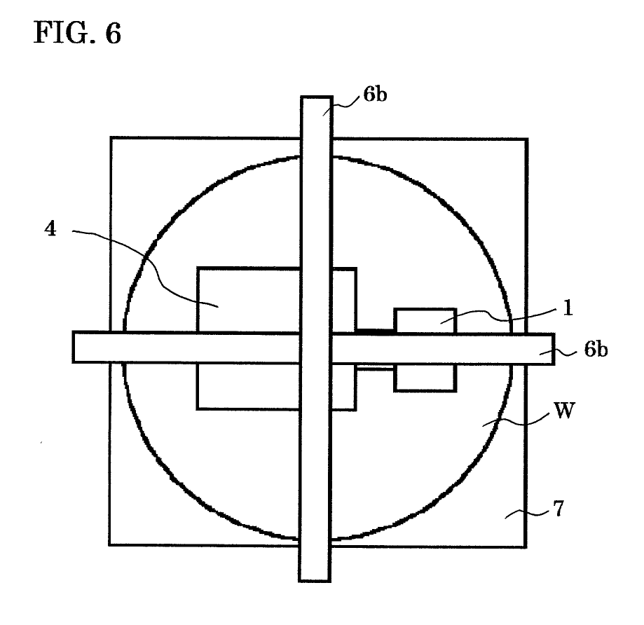

FIGS. 5 and 6 illustrate an apparatus for optically checking a pattern of a semiconductor wafer, in accordance with the second embodiment. FIG. 5 is a side view of the apparatus, and FIG. 6 is a top view of the apparatus.

The apparatus is comprised of a laser beam emitter 1 which emits a laser beam 2 to a semiconductor wafer W, a beam collector 3 which collects a laser beam reflected by the semiconductor wafer W, a photodetector 4, comprised of a CCD array in the first embodiment, which detects a pattern defect of the semiconductor wafer W, based on the laser beam collected by the beam collector 3, a X-Y stage 6b movable in directions of X and Y axes, and a stationary table 7 on which the semiconductor wafer W is placed.

The beam collector 3 and the photodetector 4 are both mounted on a lower surface of the X-Y stage 6b. In addition, the laser beam emitter 1 is fixed to the beam collector 3 through a connector 8 unlike the above-mentioned embodiment. Hence, the beam collector 3, the photodetector 4 and the laser beam emitter 1 move together in directions of X and Y axes together wit the X-Y table 6b. That is, the beam collector 3 can move to anywhere in an area above the semiconductor wafer W.

In operation, the laser beam emitter 1 radiates the laser beam 2 to the semiconductor wafer W fixed on the stationary table 7. The laser beam 2 would be diffracted or scattered, if the laser beam 2 is reflected at a pattern defect.

The beam collector 3 collects the reflected laser beams 2, and focuses the thus collected laser beams 2 on the photodetector 4 to thereby form images in the photodetector 4. Based on the images, a pattern defect is detected.

The second embodiment provides the same advantage as the advantage provided by the first embodiment. That is, the apparatus in accordance with the second embodiment can be fabricated in a space about one-fourth of a space which the conventional apparatus needs.

While the present invention has been described in connection with certain preferred embodiments, it is to be understood that the subject matter encompassed by way of the present invention is not to be limited to those specific embodiments. On the contrary, it is intended for the subject matter of the invention to include all alternatives, modifications and equivalents as can be included within the spirit and scope of the following claims.

The entire disclosure of Japanese Patent Application No. 11-345280 filed on Dec. 3, 1999 including specification, claims, drawings and summary is incorporated herein by reference in its entirety.

What is claimed is:

1. An apparatus for optically checking a pattern of a semiconductor wafer, comprising:
(a) a laser beam source which radiate a laser beam to said pattern;
(b) a beam collector which collects a laser beam reflected from said pattern; and
(c) a photodetector which detects a defect in a shape in said pattern, based on said laser beam collected by said beam collector,
said beam collector being movable in an area above said semiconductor wafer.

2. The apparatus as set forth in claim 1, wherein said beam collector is movable in a two-dimensional area.

3. The apparatus as set forth in claim 1, wherein said photodetector is integral with said beam collector such that said photodetector is movable together with said beam collector.

4. An apparatus for optically checking a pattern of a semiconductor wafer, comprising:
(a) a laser beam source which radiate a laser beam to said pattern;
(b) a beam collector which collects a laser beam reflected from said pattern; and
(c) a photodetector which detects a defect in a shape in said pattern, based on said laser beam collected by said beam collector,
said laser beam source and said beam collector being movable together in an area above said semiconductor wafer.

5. The apparatus as set forth in claim 4, wherein said laser beam source and said beam collector are movable in a two-dimensional area.

6. The apparatus as set forth in claim 4, wherein said photodetector is integral with said laser beam source and said beam collector such that said photodetector is movable together with said laser beam source and said beam collector.

7. A method of optically checking a pattern of a semiconductor wafer, comprising the steps of:
(a) radiating a laser beam to said pattern;
(b) moving a beam collector in an area above said semiconductor wafer for collecting a laser beam reflected from said pattern; and
(c) detecting a defect in a shape in said pattern, based on said laser beam collected in said step (b).

8. The method as set forth in claim 7, wherein said beam collector is moved in a two-dimensional area in said step (b).

9. A method of optically checking a pattern of a semiconductor wafer, comprising the steps of:
(a) radiating a laser beam from a laser beam source to said pattern;
(b) moving both said laser beam source and a beam collector in an area above said semiconductor wafer for collecting a laser beam reflected from said pattern; and
(c) detecting a defect in a shape in said pattern, based on said laser beam collected in said step (b).

10. The method as set forth in claim 9, wherein said beam collector is moved in a two-dimensional area in said step (b).
